(19) United States
(12) Patent Application Publication
(10) Pub. No.: US 2004/0163233 A1
(43) Pub. Date: Aug. 26, 2004

(54) Methods of forming electrical connections within ferroelectric devices

(76) Inventors: Stefan Gernhardt, Kanagawa-ken (JP); Osamu Hidaka, Kanagawa-ken (JP); Jenny Lian, Tokyo-to (JP); Rainer Bruchhaus, Kanagawa-ken (JP); Andreas Hilliger, Kanagawa-ken (JP); Nicolas Nagel, Kanagawa-ken (JP)

Correspondence Address: LERNER, DAVID, LITTENBERG,, KRUMHOLZ & MENTLIK, 600 SOUTH AVENUE WEST, WESTFIELD, NJ, 07090, US

(21) Appl. No.: 10/377,156

(22) Filed: Feb. 26, 2003

(51) Int. Cl. H01F 7/06; H05K 3/02

(52) U.S. Cl. 29/602.1; 29/846; 29/847

(57) ABSTRACT

A fabrication process for ferroelectric capacitors includes forming openings 23, 30, in the device, into which electrically conductive material 28, 37 can be inserted to form electrical connections within the device. The surface of each opening is coated with a layer 24, 34 of getter material which absorbs contaminants 25, 31, 33 formed during the opening process. This means that in subsequent processing steps the contaminants do not vagabond towards the ferroelectric layers 7 of the device where they might otherwise cause damage, for example during a subsequent crystallisation stage.

### FIELD OF THE INVENTION

The present invention relates to a method of forming a ferroelectric device, and to devices formed using the method.

### BACKGROUND OF INVENTION

It is known to produce ferroelectric devices having a multilayer structure and including ferroelectric capacitors. The ferroelectric capacitors (“ferrocapacitors”) are produced using a structure in which the following layers are deposited onto a substructure: a bottom electrode layer, a ferroelectric layer, and a top electrode layer. Hardmask elements, typically formed Tetraethyl Orthosilicate (TEOS), are deposited over the top electrode, and used to etch the structure so as to remove portions of the bottom electrode layer, ferroelectric layer, and top electrode layer which are not under the hardmask elements. Subsequently, an insulating material such as TEOS is deposited over the ferrocapacitors.

A typical structure formed by such a process is as shown in cross-section in FIG. 1(a), including a substructure 1, and deposited on it, a barrier layer 3, a bottom electrode 5, a ferroelectric layer 7, a top electrode 9, a top electrode hardmask 11 (which was used to pattern the top electrode layer to form the top electrode 9 and a bottom electrode hardmask 13 (which was used to pattern the bottom electrode layer to form the bottom electrode 5. Also present is an barrier structure comprising Al₂O₃ layers 15, 19 and a buffer layer 17 formed of TEOS. This structure is covered by TEOS layer 21,

Typically, the substructure 1 includes other electronic components (not shown) on other layers. In FIG. 1(a), a portion 2 of such a component is shown, but components on the layer are spaced from the ferrocapacitor shown in FIG. 1(a) by an insulating TEOS layer 4.

The ferrocapacitor, consisting of the bottom electrode 5, ferroelectric layer 7 and top electrode 9, is connected to the lower layers of the substructure using conductive (polysilicon or tungsten) plugs. In some known ferrocapacitors such plugs are connected to the bottom electrodes, but this is not true of the structure shown in FIG. 1(a). Instead, the top electrode 9 of that structure is connected. to elements of the substructure by the following steps.

In a first step, illustrated in FIG. 1(b), a contact window 23 is formed by a first contact etch process penetrating through the TEOS 21, the Al₂O₃ structure 15, 17, 19, the bottom electrode hardmask 13 and the top elecrode 11, terminating directly over the top electrode 9. The formation of the contact window 23 causes the generation of contamination 25 on the walls of the contact window 23.

Subsequently, a BEOL (back end of line) step is performed including a crystallisation stepperformed at a temperature of 600 C in oxygen ambient. During this process, the contamination 25 vagabonds to the ferroelectric layer 7, where it causes damage to the ferroelectric layer.

In a second step, illustrated in FIG. 1(c), a layer 27 of Nb/NbN/Nb is deposited over the structure of FIG. 1(b) and then a layer 28 of metal (Aluminium) is deposited over the structure. The layer 27 is also referred to as a “contact liner” and is for improving the fill behaviour of the layer 28.

In a third step, illustrated in FIG. 1(d), the portions of the layers 27, 28 above the top of the TEOS layer 21 are removed, leaving the contact window 23 full of metal.

In a fourth step, illustrated in FIG. 1(e), a TEOS layer 29 is deposited over the structure shown in FIG. 1(d), and subsequently a second contact window 30 is formed by a second contact etch process which is different from the first contact etch process in time and selectivity. The contact window 30 penetrates through the TEOS layer 29, TEOS layer 21, Al₂O₂ barrier structure 15, 17, 19, and into the TEOS layer 4 of the substructure 1. The second contact window passes through the TEOS layer 4 and terminates at the top of the portion 2 of one of the lower components. During this step, contamination 31 is formed on the sides of the second contact window 30.

If a fifth step, illustrated in FIG. 1(f), part of the TEOS layer 29 (and also part of the TEOS layer 21) is partially removed, to form a trench 32 extending laterally between the contact windows 23, 30. This step generates further contamination 33 on the walls of the trench.

Subsequently, in a sixth step illustrated in FIG. 1(g), another layer 35 of Nb/NbN/Nb is deposited over the inner surface of the trench, and a layer 37 of metal (Aluminium) is then deposited over the entire structure, Again, the purpose of the layer 35 is to improve the fill behaviour of the metal 37. Thus, the portion 2 of the components in the lower layer 2 is electrically connected to the top electrode 9 of the ferrocapacitor via the metal in the contact window 23, the metal layer 37 and layers 27, 35.

The material above the upper surface of the TEOS layer 29 is then removed to give the completed structure shown in FIG. 1(h).

The process may be repeated as desired to build up a series of layers. During each BEOL step the contamination 25, 31, 33 vagabonds to the ferroelectric layer 7, where it causes damage to the ferroelectric layer.

### SUMMARY OF THE INVENTION

The present invention aims to provide a new and useful method for producing ferroelectric devices, and in particular one with a reduced chance of damage to the ferroelectric layer by contaminants.

In general terms, the invention proposes that during the fabrication process of a device including one or more ferroelectric capacitors, following a step of forming an opening for housing an electrical connection, a layer of a getter material is formed on the surface of the opening. The getter material is one which can absorb contaminants formed during the opening process, so that in subsequent processing steps the contaminants are retained by the getter material, and do not move to the ferrocapacitors where they can potentially cause damage.

The opening may be an opening which principally extends downwardly in the structure for forming vertical electrical connections (such as a contact window), Alternatively, it may be an opening which extends principally laterally for electrically connecting components at substantially the same level in the structure (such as a trench).

The contaminants are typically hydrogen compounds, so that a layer of Ti and/or TIN would be suitable to act as a getter layer.

### BRIEF DESCRIPTION OF THE FIGURES

Preferred features of the invention will now be described, for the sake of illustration only, with reference to the following figures in which:

FIG. 1, which is composed of FIGS. 1(a) to 1(h), shows in cross-section the steps of a known technique for producing electrical connections within a ferroelectric device;

FIG. 2, which is composed of FIGS. 2(a) to 2(c), shows how steps in the known method are modified in a method which is an embodiment of the invention.

### DETAILED DESCRIPTION OF THE EMBODIMENTS

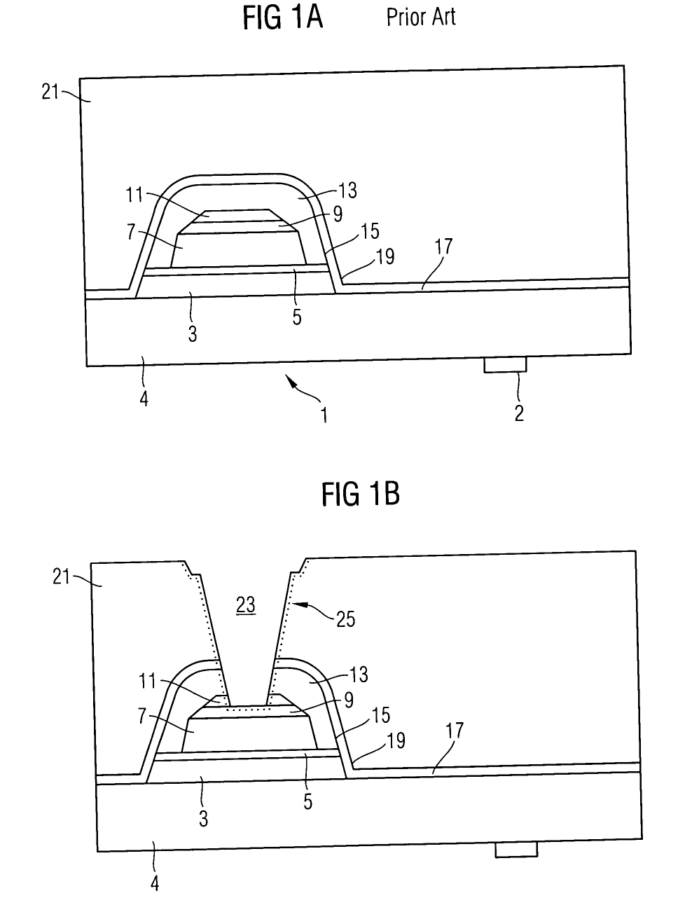

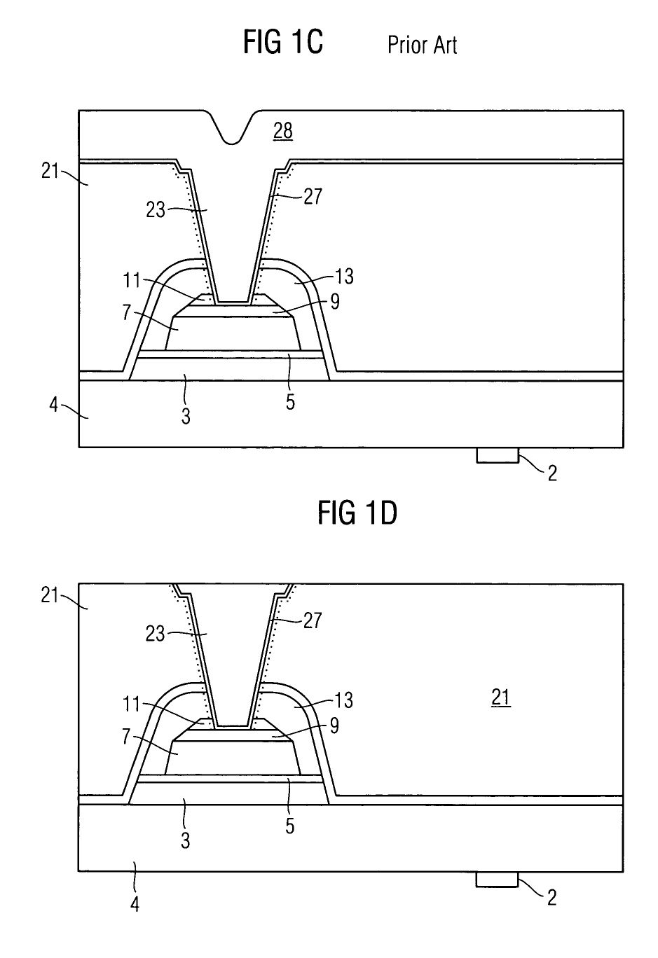

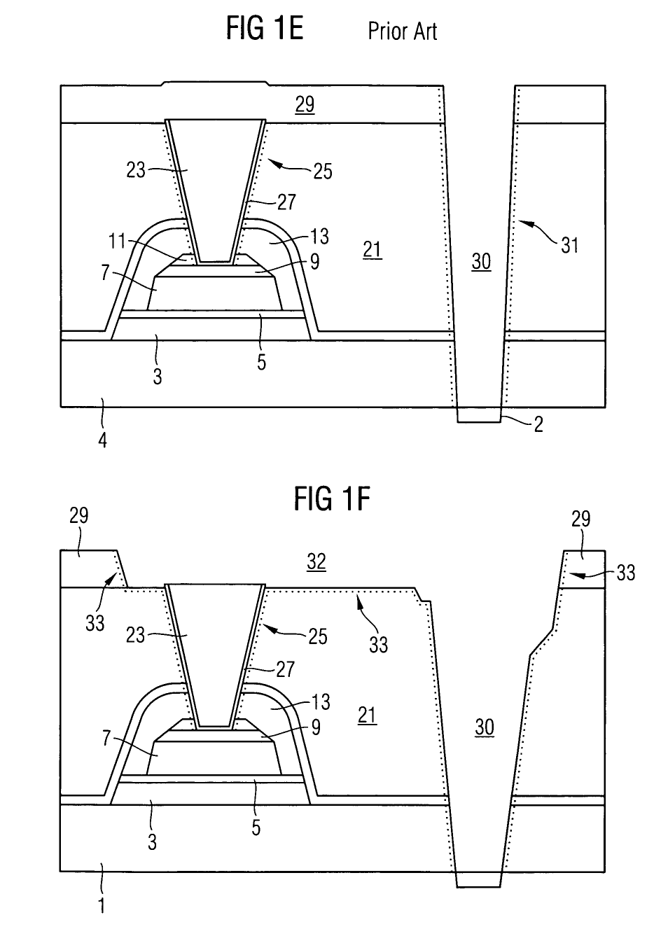

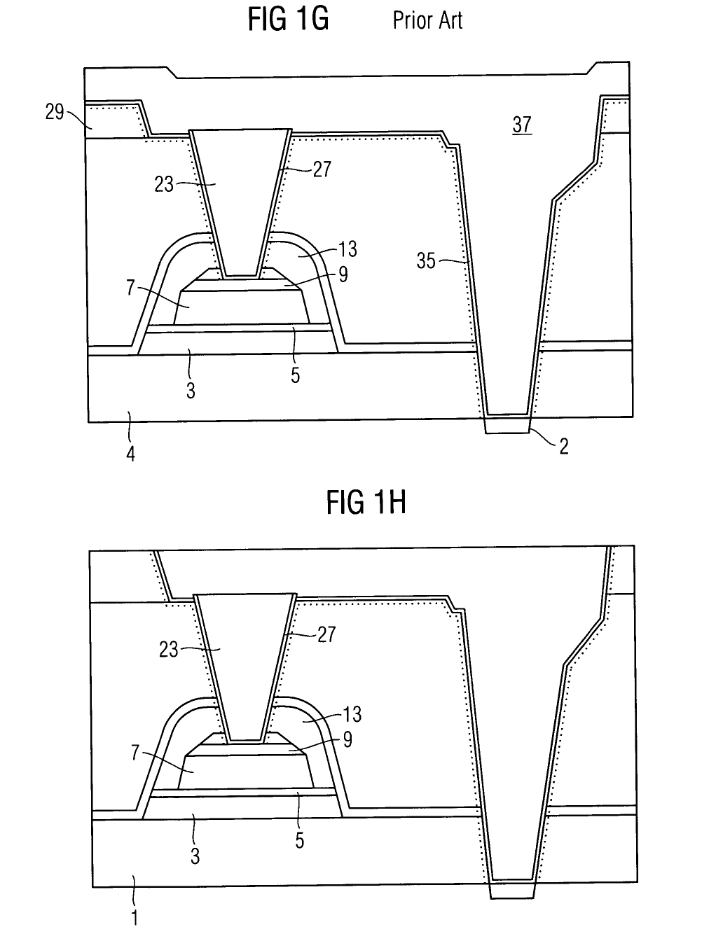

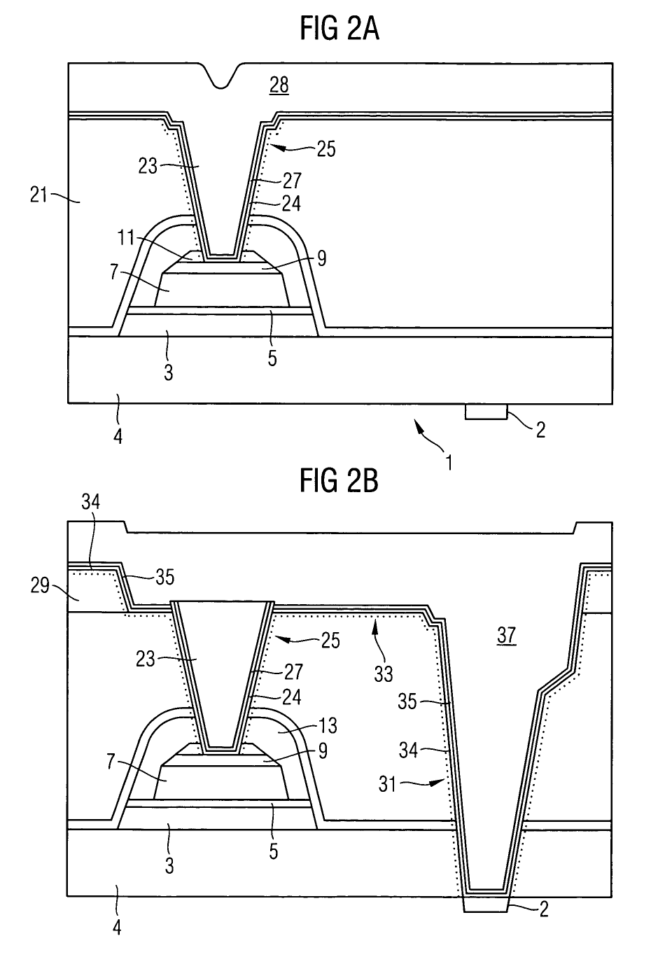

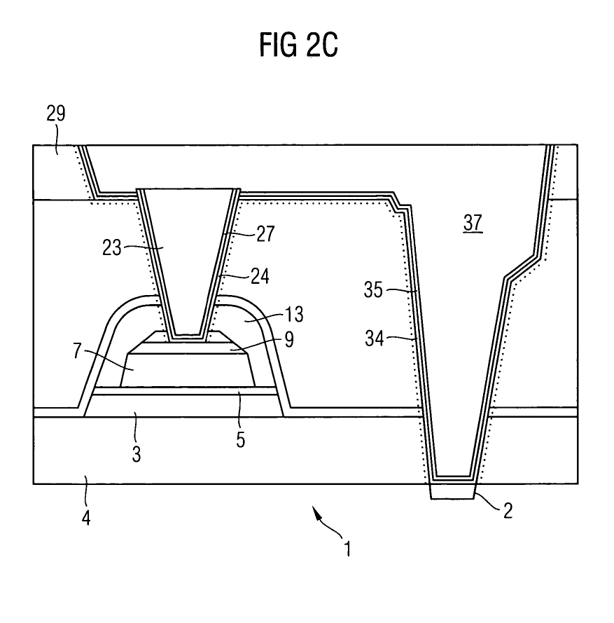

The method which is an embodiment of the invention resembles the known technique illustrated in FIGS. 1(a) to 1(h), and for that reason the embodiment will be explained by means of FIG. 2(a) to FIG. 2(c) which use the same reference numerals as in FIGS. 1(a) to 1(h) to label the corresponding elements.

The starting point of the embodiment is the structure shown in FIG. 1(b). However, the embodiment proposes that, prior to the deposition of the layers 27, 28 illustrated in FIG. 1(c), a layer 24 of a getter material such as Ti and/or TiN is coated on the conical surface of the well 23, so that after the deposition of the layers 27, 28 the structure is as shown in FIG. 2(a).

Subsequently, the process steps of the embodiment are as the same as the steps illustrated in FIGS. 1(d)-1(f). That is, the portions of the layers 24, 27, 28 above the top of the TEOS layer 21 are removed, leaving the contact window 23 full of metal. A TEOS layer 29 is deposited over the structure. A second contact window 30 is formed, penetrating through the TEOS layer 29, TEOS layer 21, a barrier structure comprising layers of Al₂O₂ 15, 19 and a TEOS buffer layer 17, and into the substructure 1 where it terminates at the top of the portion 2 of one of the lower components. During this step, contamination 31 is formed on the sides of the second contact window 30. Then part of the TEOS layer 29 (and also part of the TEOS layer 21) is partially removed, to form a trench 32 extending laterally. This step generates further contamination 33 on the walls of the trench.

However, before the deposition of the layers 35, 37 (i.e. the step of the conventional method shown in FIG. 1(g)), the present invention further proposes that a layer 34 of a getter material is deposited over the structure. Then, as in the step of the known method shown in FIG. 1(g), a layer 35 of Nb/NbN/Nb is formed over the getter layer 34, and the device is covered with metal material 37. This gives the structure shown in FIG. 2(b).

The final step of the method is the removal of the material above the top of the layer 29. This gives the completed structure shown in FIG. 2(c). This structure is identical to that of FIG. 1(h), except for the presence of the layers 24, 34 of getter material. The layers 24, 34 of getter material trap the contamination 25, 31, 33 so that it does not vagabond to the ferroelectric layer 7 during subsequent BEOL processes.

Although only a single embodiment of the invention has been illustrated in detail, many variations are possible within the scope of the invention, as will be clear to a skilled reader. For example, many methods are known for the formation of openings through electronic devices including ferrocapacitors, so that the openings can be used to provide conductive paths. The present invention may be implemented in almost any such method, for forming a layer of getter material on the sides of the opening including contaminants.

1. A method of forming electrical connections during a fabrication process of a device including ferroelectric capacitors, the method including the steps of
forming an opening in the device for receiving electrically conductive material for forming an electrical connection;
depositing a layer of a getter material on the surface of the opening; and
filling the opening with electrically conductive material.

2. A method according to claim 1 in which the opening extends principally vertically in the structure for forming vertical electric paths.

3. A method according to claim 2 in which the opening terminates on a top electrode of a ferrocapacitor.

4. A method according to claim 2 in which the opening extends between different layer of the structure.

5. A method according to claim 1 in which the opening extends principally laterally for electrically connecting components at substantially the same level in the structure.

6. A method according to claim 1 in which the getter layer comprises Ti and/or TiN.

7. A method according to claim 1 in which a layer comprising Nb and/or NbN is deposited over the getter layer before the opening is filled with electrically conductive material.

8. A method according to claim 1 in which the opening is formed by RIE etching.

9. A method according to claim 1 in which the opening is formed in a layer of TEOS.

10. A method of forming a ferroelectric device, the method comprising: forming a bottom electrode, a ferroelectric layer, and a top layer,
forming hardmask elements over the top electrode layer,
etching at least the top electrode and ferroelectric layer using the hardmask elements to form ferrocapacitors,
forming an electrically insulating layer over the ferrocapacitors, and
forming one or more electrical connections in the insulating layer by a method according to claim 1.

11. A ferroelectric device formed by a method according to claim 10.
